(19) United States
(12) Patent Application Publication
(10) Pub. No.: US 2025/0329355 A1
(43) Pub. Date: Oct. 23, 2025

(54) SYSTEMS AND METHODS FOR DATA SYNCHRONIZATION

(71) Applicant: Thomas J. Patterson, Fort Irwin, CA (US)

(72) Inventor: Thomas J. Patterson, Fort Irwin, CA (US)

(21) Appl. No.: 18/805,418

(22) Filed: Aug. 14, 2024

Related U.S. Application Data
(60) Provisional application No. 63/635,710, filed on Apr. 18, 2024.

(51) Int. Cl. G11C 7/10; G11C 11/4093

(52) U.S. Cl. CPC G11C 7/1072; G06F 5/08; G11C 11/4093

(57) ABSTRACT

Embodiments describe a data synchronization mechanism, focusing on the efficient management of a circular buffer between producer and consumer processes. In an embodiment, a method uses a lapping technique to facilitate parallel processing without the need for locking mechanisms, ensuring continuous data flow and real-time responsiveness. Further, the method uses a paperclipping technique to record the state of the buffer prior to lap transitions to accurately determine buffer fullness without ambiguity, even when the producer and consumer pointers coincide. Additionally, a reset technique enables the system to mitigate dropped production items by allowing the producer to overwrite outdated data when the buffer is full, and the consumer is lagging. The mechanism is hardware-independent, operating system-agnostic, and can be implemented across various programming languages, making it highly adaptable for a broad range of applications in computing systems.

### TECHNICAL FIELD

The present disclosure relates to data storage systems, and more particularly, relates to computer-implemented systems and methods for data synchronization.

### BACKGROUND

Embedded systems are specialized computing systems designed to perform dedicated functions or manage specific tasks within larger systems. Unlike general-purpose computers that can run a wide range of applications, embedded systems are optimized for efficiency and reliability in their target application. They are integral to a variety of devices, ranging from simple household appliances like microwaves and washing machines to complex systems such as automotive control systems, medical devices, and industrial machines.

In the context of embedded systems, buffers play a crucial role in managing data flow between different components or systems. A buffer is a temporary storage area used to hold data while it is being moved from one place to another, ensuring smooth and efficient data handling. This is particularly important in embedded systems where data must often be processed in real-time or where the system interfaces with external devices that operate at different speeds.

There are various types of buffers including, but not limited to, circular buffers, Direct Memory Access (DMA) buffers, and Input/Output (IO) buffers. Circular buffers are often used in embedded systems for their efficiency in situations where data is produced and consumed at different rates. Circular buffers are particularly useful in serial communication and streaming data applications. DMA buffers are used when data needs to be transferred between peripherals and memory without continuous processor intervention, improving system performance. IO buffers are used to balance the data flow between the system's core logic and its input/output interfaces, crucial for ensuring responsive and reliable system operation.

Effective buffer management is vital in embedded systems to prevent data loss, avoid buffer overflows, and ensure timely data processing. This includes techniques for determining when buffers are full or empty, managing read/write pointers, and handling buffer resets or overwrites in cases where real-time data processing is critical. Buffers within these systems are essential for managing data flow, ensuring that embedded systems can meet their real-time performance and reliability requirements.

A fundamental challenge in computing and embedded systems is efficiently determining whether a shared circular buffer is full or empty to enable parallel processing without complex, inefficient, or hardware-dependent solutions. This challenge highlights the difficulties in ensuring that a producer entity does not overwrite data in a buffer that a consumer entity has not read yet, and conversely, that the consumer entity does not read the same data more than once or attempt to read data from an empty buffer. It is a state that must be reliably determined even during context switches and when variables are updated. This challenge, often referred to as the producer-consumer problem, has persisted in computing since its early days, with various approaches attempting to resolve it, each with its limitations.

Traditional solutions have either involved locking mechanisms, which force the producer entity and the consumer entity to operate sequentially, or non-locking mechanisms that depend on specific hardware capabilities or involve data copying to maintain atomicity. In traditional systems, achieving parallel processing often means sacrificing a buffer slot to clearly demarcate the full or empty states of the buffer, which may not always be feasible, especially with large buffers.

In the locking mechanisms, mutual exclusion is used to prevent multiple threads from accessing a shared resource (e.g., buffer) at the same time. While effective in preventing data corruption, mutual exclusion can lead to deadlocks, where two processes are each waiting for the other to release a lock. Further, semaphores are used to allow a certain number of threads to access a resource concurrently. However, semaphores still introduce overhead and complexity, can lead to priority inversion, and are susceptible to issues like semaphore leakage, where a thread fails to release a semaphore, leading to blockages.

A few traditional solutions were implemented using critical sections, i.e., parts of the code that must not be executed by more than one thread or process at the same time. Managing access to critical sections requires careful design to avoid deadlocks and ensure that no thread is starved of resources. This management often involves complex algorithms and significant overhead, especially in systems with many concurrent threads.

Some traditional solutions use busy waiting or polling mechanisms to check the status of the buffer continuously. This approach is resource-intensive and inefficient since it involves repeatedly executing a loop until the condition changes, consuming valuable processor time that could be used for other tasks. Busy waiting is often due to mutual exclusion in the critical section.

Single-threaded approaches simplify buffer management by avoiding concurrent access issues but at the cost of parallelism, significantly reducing system throughput. Blocking solutions, where the producer entity or the consumer entity waits until an item is removed or added, respectively, can lead to deadlocks, priority inversion, underutilization of system resources, and increased latency.

In view of the above, problems with traditional solutions include resource efficiency, complexity, real-time performance, and scalability. Many traditional solutions require additional resources, such as memory for semaphore variables or Central Processing Unit (CPU) cycles for busy waiting, which could be prohibitive in resource-constrained embedded systems. Implementing and maintaining solutions involving locks, semaphores, or critical sections can significantly increase the complexity of embedded software, making it harder to debug and verify. Ensuring real-time performance with traditional solutions can be challenging, especially in systems with strict timing constraints. Overhead introduced by synchronization mechanisms can lead to missed deadlines. As the number of concurrent threads increases, managing access to shared resources becomes more complex and error-prone, impacting the scalability of traditional solutions.

Therefore, based on the above, there exists a technological need for an improved, efficient, and reliable computer-implemented system and method for data synchronization, especially for circular buffers.

### SUMMARY

In an aspect, the present disclosure relates to a system for data synchronization, including a processor, and a memory operatively coupled to the processor, the memory including processor-executable instructions which, when executed, cause the processor to determine a producer lap indicator, associated with a producer entity, corresponding to a buffer, determine a consumer lap indicator associated with a consumer entity, determine a state of the buffer based on the producer lap indicator and the consumer lap indicator, and in response to a determination of the state of the buffer being full or empty, enable data synchronization based on initiating lapping and/or paperclipping at the buffer.

In an embodiment, to initiate the paperclipping, the processor may be configured to record a producer paperclip indicator and a consumer paperclip indicator prior to a change in the respective producer lap indicator and the consumer lap indicator associated with the producer entity and the consumer entity, and determine the state of the buffer based on the producer paperclip indicator and the consumer paperclip indicator.

In an embodiment, to initiate the lapping, the processor may be configured to determine a position of an in-pointer, associated with the producer entity, corresponding to the buffer, determine a position of an out-pointer associated with the consumer entity, determine the state of the buffer further based on the position of the in-pointer and the position of the out-pointer, in response to the state of the buffer being full, restrict the producer entity to write data to the buffer, or the consumer entity to read data from the buffer until an item is removed or added respectively, for a predetermined duration of time, in response to the state of the buffer being empty, enable the producer entity to write the data to the buffer at the position of the in-pointer in the buffer, or the consumer entity to read the data from the position of the out-pointer in the buffer.

In an embodiment, the processor may be configured to initiate the paperclipping based on the position of the in-pointer being same as the position of the out-pointer where lap change occurs.

In an embodiment, in response to the state of the buffer being full, the processor may be configured to set a producer flag associated with the producer entity to 1, indicating that the buffer is full.

In an embodiment, the processor may be further configured to reset the consumer lap indicator and the position of the out-pointer to 0, and set a consumer flag associated with the consumer entity to 1.

In an embodiment, the processor may be further configured to based on the consumer flag being set to 1, reset the producer lap indicator and the position of the in-pointer to 0, and the producer flag to 0, based on the producer flag being set to 0, set the consumer flag to 0 and wait for the data to be written to the buffer, and based on the consumer flag being set to 0, enable the producer entity to write the data to the buffer.

In an embodiment, the processor may be further configured to set a consumer flag associated with the consumer entity, the position of the out-pointer, the consumer lap indicator, and the consumer paperclip indicator as equal to the respective producer flag, the position of the in-pointer, the producer lap indicator, and the producer paperclip indicator, and restrict the producer entity to write the data until the consumer flag is 0.

In an embodiment, the state of the buffer may be empty when the producer lap indicator and the consumer lap indicator are equal and/or the position of the in-pointer is equal to the position of the out-pointer, and the state of the buffer maybe full when the producer lap indicator and the consumer lap indicator are not equal.

In another aspect, the present disclosure relates to a method for data synchronization, including determining, by a processor, a producer lap indicator, associated with a producer entity, corresponding to a buffer, determining, by the processor, a consumer lap indicator associated with a consumer entity, determining, by the processor, a state of the buffer based on the producer lap indicator and the consumer lap indicator, and in response to determining that the state of the buffer is full or empty, enabling, by the processor, data synchronization based on initiating lapping and/or paperclipping at the buffer.

In an embodiment, to initiate the paperclipping, the method may include recording, by the processor, a producer paperclip indicator and a consumer paperclip indicator prior to a change in the respective producer lap indicator and the consumer lap indicator associated with the producer entity and the consumer entity, and determining, by the processor, the state of the buffer further based on the producer paperclip indicator and the consumer paperclip indicator.

In an embodiment, to initiate the lapping, the method may include determining, by the processor, a position of an in-pointer, associated with the producer entity, corresponding to the buffer, determining, by the processor, a position of an out-pointer associated with the consumer entity, determining, by the processor, the state of the buffer further based on the position of the in-pointer and the position of the out-pointer, in response to the state of the buffer being full, restricting, by the processor, the producer entity to write data to the buffer, or the consumer entity to read data from the buffer until an item is removed or added respectively, for a predetermined duration of time, and in response to the state of the buffer being empty, enabling, by the processor, the producer entity to write the data to the buffer at the position of the in-pointer in the buffer, or the consumer entity to read the data from the position of the out-pointer in the buffer where lap change occurs.

In an embodiment, initiating the paperclipping may be based on the position of the in-pointer being same as the position of the out-pointer.

In an embodiment, in response to the state of the buffer being full, the method may include setting, by the processor, a producer flag associated with the producer entity to 1, indicating that the buffer is full.

In an embodiment, the method may include resetting, by the processor, the consumer lap indicator and the position of the out-pointer to 0, and setting, by the processor, a consumer flag associated with the consumer entity to 1.

In an embodiment, the method may include, based on the consumer flag being set to 1, resetting, by the processor, the producer lap indicator and the position of the in-pointer to 0, and the producer flag to 0, based on the producer flag being set to 0, setting, by the processor, the consumer flag to 0 and waiting for the data to be written to the buffer, and based on the consumer flag being set to 0, enabling, by the processor, the producer entity to write the data to the buffer.

In an embodiment, the method may include setting, by the processor, a consumer flag associated with the consumer entity, the position of the out-pointer, the consumer lap indicator, and the consumer paperclip indicator as equal to the respective producer flag, the position of the in-pointer, the producer lap indicator, and the producer paperclip indicator, and restricting, by the processor, the producer entity to write the data until the consumer flag is 0.

In an embodiment, the state of the buffer may be empty when the producer lap indicator and the consumer lap indicator are equal and/or the position of the in-pointer is equal to the position of the out-pointer, and the state of the buffer maybe full when the producer lap indicator and the consumer lap indicator are not equal.

In another aspect, the present disclosure relates to a non-transitory computer-readable medium comprising executable instructions that cause a processor to determine a producer lap indicator, associated with a producer entity, corresponding to a buffer, determine a consumer lap indicator associated with a consumer entity, determine a state of the buffer based on the producer lap indicator and the consumer lap indicator, and in response to a determination of the state of the buffer being full or empty, enable data synchronization based on initiating lapping and/or paperclipping at the buffer.

### BRIEF DESCRIPTION OF THE FIGURES

The following detailed description of illustrative embodiments is better understood when read in conjunction with the appended drawings. To illustrate the present disclosure, exemplary constructions of the disclosure are shown in the drawings. However, the present disclosure is not limited to a specific device, or a tool and instrumentalities disclosed herein. Moreover, those in the art will understand that the drawings are not to scale.

FIG. 1 illustrates an example representation of a network architecture, in accordance with embodiments of the present disclosure;

FIG. 2 is a simplified block diagram of a server for facilitating data synchronization, in accordance with embodiments of the present disclosure;

FIG. 3 illustrates a flow chart of an example method for multiple buffer lapping, in accordance with embodiments of the present disclosure;

FIG. 4 illustrates a flow chart of an example method for single buffer lapping, in accordance with embodiments of the present disclosure;

FIG. 5 illustrates a flow chart of an example method for implementing lapping reset, in accordance with embodiments of the present disclosure; and

FIG. 6 illustrates an example computer system in which or with which embodiments of the present disclosure may be utilized in accordance with embodiments of the present disclosure.

The drawings referred to in this description are not to be understood as being drawn to scale except if specifically noted, and such drawings are only exemplary in nature.

### DETAILED DESCRIPTION

In the following description, for purposes of explanation, numerous specific details are set forth in order to provide a thorough understanding of the present disclosure. It will be apparent, however, to one skilled in the art that the present disclosure can be practiced without these specific details. Descriptions of well-known components and processing techniques are omitted to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

Reference in this specification to “one embodiment” or “an embodiment” means that a particular feature, structure, or characteristic described in connection with the embodiment is included in at least one embodiment of the present disclosure. The appearances of the phrase “in an embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

Various examples of the present disclosure provide computer-implemented systems and methods for facilitating data synchronization.

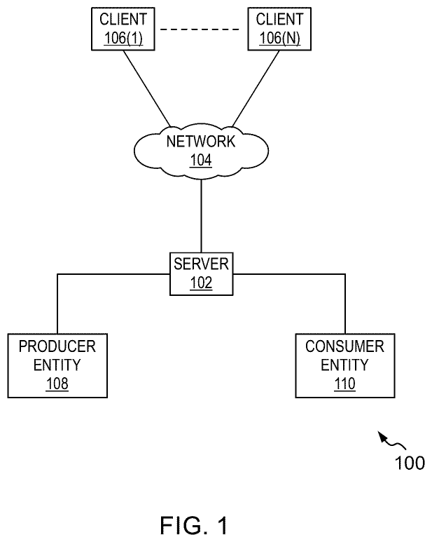

Various embodiments of the present invention are described hereinafter with reference to FIG. 1 to FIG. 6.

FIG. 1 illustrates an example representation of a network architecture 100, in accordance with embodiments of the present disclosure. Although the network architecture 100 is presented in one arrangement, other embodiments may include the parts of the network architecture 100 (or other parts) arranged otherwise depending on, for example, for facilitating data synchronization.

The network architecture 100 generally includes a server 102 (interchangeably referred as the “system 102”) and one or more clients (106(1) . . . 106(N)). It should be noted that for ease of reference, the one or more clients (106(1) . . . 106(N)) may be collectively referred to as the clients 106 and individually referred to as the client 106. The clients 106 and the server 102 are coupled to, and in communication with (and/or with access to) a network 104. In some embodiments, each client 106 sends requests to and receives responses from the server 102 via the network 104. In some embodiments, the clients 106 may generate data and/or consume data.

In some embodiments, the network 104 may include, without limitation, a Light Fidelity (Li-Fi) network, a Local Area Network (LAN), a Wide Area Network (WAN), a metropolitan area network (MAN), a satellite network, the Internet, a fiber-optic network, a coaxial cable network, an Infrared (IR) network, a Radio Frequency (RF) network, a virtual network, and/or another suitable public and/or private network capable of supporting communication among the entities illustrated in FIG. 1, or any combination thereof.

Various entities in the network architecture 100 may connect to the network 104 in accordance with various wired and wireless communication protocols, such as Transmission Control Protocol and Internet Protocol (TCP/IP), User Datagram Protocol (UDP), 2nd Generation (2G), 3rd Generation (3G), 4th Generation (4G), 5th Generation (5G) communication protocols, Long Term Evolution (LTE) communication protocols, or any combination thereof. For example, the network 104 may include multiple different networks, such as a private network made accessible by the clients 106, and a public network (e.g., Internet) through which the clients 106 and the server 102 may communicate.

Referring to FIG. 1, the server 102 may act as a central hub that processes requests from the clients 106 and facilitates data exchange between a producer entity 108 and a consumer entity 110. In accordance with embodiments of the present disclosure, the server 102 may synchronize data exchange efficiently, ensuring that a buffer managed by the server 102 is accurately and efficiently utilized. A person of ordinary skill in the art will understand that a buffer may refer to a region of physical memory storage used to temporarily store data while it is being moved from one place to another. In some embodiments, the server 102 may be deployed as a standalone server or can be implemented in the cloud as Software as a Service (SaaS). The server 102 is embodied in at least one computing device in communication with the network 104 and/or embodied in at least one non-transitory computer-readable media.

The producer-consumer problem exists around a circular buffer, because the state of the buffer, whether full or empty, needs to be known. The state of the buffer must be preserved during context switches, and when variables are updated. Traditionally, the solutions to accomplish this have been locking mechanisms that require the producer entity 108 and the consumer entity 110 to operate one at a time, and non-locking mechanisms that require the use of hardware or copying to maintain atomicity.

Lapping includes that if two runners are side by side, then either they are tied or one is ahead of the other. On a buffer that equates to empty or full, if the runners are not side by side, then there is catching up to do, or outlapping the other runner; this means producing and consuming on demand without waiting one at a time for one another. Laps are represented by 0 or 1. The buffer is empty if both the producer entity 108 and the consumer entity 110 are on the same lap as at the start, and full if they are not on the same lap as in the producer entity 108 out laps the consumer entity 110. The producer entity 108 cannot produce on a full buffer and the consumer entity 110 cannot consume on an empty buffer; if the buffer is not full or empty, only one other state exists, i.e. parallel processing. Both the producer entity 108 and the consumer entity 110 indicate the completion of a transaction by moving to the next buffer slot and checking for one another before beginning a transaction at each slot to see if the buffer is full or empty. The only problem with this is when the laps change at the finish line; if the producer entity 108 and the consumer entity 110 are both at the last slot of the buffer before returning to slot 0, then their laps can be what they are before they get to slot 0 and what they will be at slot 0, while they are side by side at the slot just before slot 0. This yields two contradictory results of full and empty after the initial determination, because the consumer entity 110 or the producer entity 108 must update the lap before advancing from their present location, which will be described in detail throughout the disclosure.

The producer entity 108 may refer to a process, task, or component responsible for generating data or output. For example, the data may be anything from sensor readings in an Internet of Things (IoT) device to frames of video in a streaming application. The data will be stored in the buffer before being sent across the network 104 to the clients 106 or other systems. The role of the producer entity 108 is to ensure a steady and reliable supply of data to the shared buffer, from which the consumer entity 110 can retrieve the data for further processing or use. In accordance with embodiments of the present disclosure, the producer entity 108 does not need to wait for the consumer entity 110 to catch up before producing more data, as long as buffer space is available. This helps in reducing idle time and increases the system's responsiveness. In some embodiments, the producer entity 108 may use lapping to mark its progress in the buffer, which will be discussed in detail throughout the disclosure. In some other embodiments, when the buffer is full and the consumer entity 110 is slow, the producer entity 108 may leverage the functionality of reset to overwrite the old data with new, more relevant data, ensuring that the system always has the most up-to-date information.

The consumer entity 110 may refer to a process, task, or component responsible for consuming the data from the buffer, i.e. retrieving and processing the data generated by the producer entity 108. The consumer entity 110 reads and removes the data from the buffer for processing, for example, for displaying it to a user (or client 106), storing it for long-term use, or using it as input for further computational tasks. The consumption of data must often keep pace with the rate of production to prevent buffer underflow, where the consumer entity 110 runs out of data to process. The consumer entity 110 may need to determine whether there is data to consume. In accordance with lapping and paperclipping, the consumer entity 110 may determine if the buffer is empty or full without causing delays. It may be appreciated that the consumer entity 110 can operate in parallel with the producer entity 108, i.e., as soon as the consumer entity 110 finishes processing data from one part of the buffer, it can immediately move on to the next, thereby improving throughput. In situations where the buffer is overwritten by the producer entity 108, the consumer entity 110 can reset and start processing the latest data.

Therefore, in accordance with embodiments of the present disclosure, the server's management of the buffer is more efficient, avoiding common problems associated with traditional solutions such as deadlocks, priority inversion, and reliability on hardware-specific features. The producer entity 108 and the consumer entity 110 may work independently and in parallel, with the server 102 acting as an intermediary that ensures synchronization and proper data flow. It may be appreciated that lapping allows the server 102 to maximize buffer utilization by allowing the producer entity 108 to continue producing as long as there is space in the buffer and enabling the consumer entity 110 to consume as long as data is available. Lapping may revolutionize the use of bounded buffers in computing systems. Further, paperclipping helps resolve any ambiguity about the state of the buffer, especially at critical transaction points, ensuring data consistency and reliability.

The number and arrangement of systems, devices, and/or networks shown in FIG. 1 are provided as an example. There may be additional systems, devices, and/or networks; fewer systems, devices, and/or networks; different systems, devices, and/or networks; and/or differently arranged systems, devices, and/or networks than those shown in FIG. 1. Furthermore, two or more systems or devices shown in FIG. 1 may be implemented within a single system or device, or a single system or device is shown in FIG. 1 may be implemented as multiple, distributed systems or devices. Additionally, or alternatively, a set of systems (e.g., one or more systems) or a set of devices (e.g., one or more devices) of the network architecture 100 may perform one or more functions described as being performed by another set of systems or another set of devices of the network architecture 100.

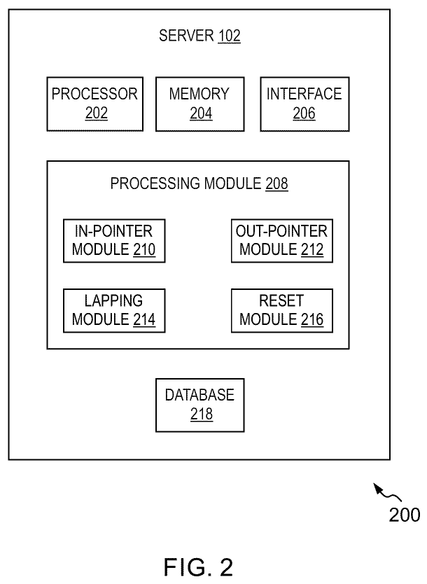

FIG. 2 is a simplified block diagram 200 of a server such as the server 102 for facilitating data synchronization, in accordance with embodiments of the present disclosure.

In some embodiments, and as shown in FIG. 2, the server 102 may include one or more processors 202. The one or more processors 202 may be implemented as one or more microprocessors, microcomputers, microcontrollers, digital signal processors, central processing units, logic circuitries, and/or any devices that manipulate data based on operational instructions. Among other capabilities, the one or more processors 202 may be configured to fetch and execute computer-readable instructions stored in a memory 204 of the server 102. The memory 204 may store one or more computer-readable instructions or routines, which may be fetched and executed to create or share the data units over a network service. The memory 204 may include any non-transitory storage device including, for example, volatile memory such as Random-Access Memory (RAM), or non-volatile memory such as an Erasable Programmable Read-Only Memory (EPROM), a flash memory, and the like.

In some embodiments, the server 102 may also include an interface(s) 206. The interface(s) 206 may include a variety of interfaces, for example, interfaces for data input and output devices, referred to as I/O devices, storage devices, and the like. The interface(s) 206 may facilitate communication of the server 102 with various devices coupled to it. The interface(s) 206 may also provide a communication pathway for one or more components of the server 102. Examples of such components include, but are not limited to, processing module(s) 208 and a database 218.

In some embodiments, the processing module(s) 208 may be implemented as a combination of hardware and programming (for example, programmable instructions) to implement one or more functionalities of the processing module(s) 208. In examples, described herein, such combinations of hardware and programming may be implemented in several different ways. For example, the programming for the processing module(s) 208 may be processor-executable instructions stored on a non-transitory machine-readable storage medium and the hardware for the one or more processors 202 may include a processing resource (for example, one or more processors), to execute such instructions. In the present examples, the machine-readable storage medium may store instructions that, when executed by the processing resource, implement the processing module(s) 208. In such examples, the server 102 may include the machine-readable storage medium storing the instructions and the processing resource to execute the instructions, or the machine-readable storage medium may be separate but accessible to the server 102 and the processing resource. In other examples, the processing module(s) 208 may be implemented by an electronic circuitry.

In some embodiments, the database 218 may include data that may be either stored or generated as a result of functionalities implemented by any of the components of the processors 202 or the processing module (s) 208 or the server 102.

It is noted that the server 102 as illustrated and hereinafter described is merely illustrative of an apparatus that could benefit from embodiments of the present disclosure, and therefore, should not be taken to limit the scope of the present disclosure. It is noted that the server 102 may include fewer or more components than those depicted in FIG. 2.

In an exemplary embodiment, the processing module(s) 208 may include one or more modules selected from any of an in-pointer module 210 corresponding to the producer entity (e.g., 108 of FIG. 1), an out-pointer module 212 corresponding to the consumer entity (e.g., 110 of FIG. 1), a lapping module 214 (also including paperclipping module and interchangeably referred to as ‘paperclipping module 214’), a reset module 216, and other modules. The other modules may include, but are not limited to, a monitoring module, a determination module, a notification module, and the like. It may be appreciated that lapping and paperclipping modules are represented as one module for ease of reference.

In some embodiments, the server 102 represents the central system that handles synchronization of I/O operations between the producer entity 108 and the consumer entity 110 using, for example, a circular buffer. The in-pointer module 210 may determine and/or store information corresponding to an in-pointer, indicating a position within the circular buffer where the producer entity 108 is currently writing data, ensuring that data is placed correctly without overwriting unconsumed data. The in-pointer module 210 integrates with the lapping module 214 to ensure that the in-pointer's movement around the buffer is accurately reflected in the lapping count. The out-pointer module 212 may determine and/or store information corresponding to an out-pointer, indicating a position within the circular buffer where the consumer entity 110 is reading data. The out-pointer module 212 integrates with the paperclipping module (also 214) to resolve any potential ambiguities when the pointers are at the same location, ensuring reliable data consumption.

In some embodiments, the lapping module 214 may initiate a lapping operation and/or a paperclipping operation. For example, the lapping module 214 may initiate the lapping operation to track the laps of the in-pointer associated with the in-pointer module 210 and the out-pointer associated with the out-pointer module 212 around the circular buffer to determine when the buffer is full or empty without requiring locks. The lapping module 214 may determine a producer lap indicator associated with the producer entity 108 and a consumer lap indicator associated with the consumer entity 110. A lap is considered to be completed when a pointer returns to its starting point after traversing the entire buffer. The functions of the lapping operation may include, but are not limited to, pointer tracking, buffer state determination, synchronization without locks, facilitating parallel processing, and wait-free operations.

In some embodiments, the lapping module 214 may monitor the in-pointer module 210 and the out-pointer module 212, i.e., the positions of the in-pointer and the out-pointer within the circular buffer, thereby effectively tracking how many times each pointer has lapped the buffer. Utilizing the count of the laps, the lapping module 214 may determine the state of the buffer, for example, full, empty, or partially filled. This is crucial for enabling the producer entity 108 to determine when it can safely write data to the buffer and for the consumer entity 110 to determine when it can read the data from the buffer without any data loss or collision.

By keeping track of the laps, the lapping module 214 may allow the system (or the server 102) to synchronize the actions of the producer entity 108 and the consumer entity 110. This is especially advantageous in real-time systems where lock contention may lead to unacceptable delays. The lapping operation allows the producer entity 108 and the consumer entity 110 to process in parallel, improving the overall throughput of the system. The lapping module 214 coordinates these parallel operations to maintain system integrity. Since the lapping module 214 can provide immediate information about the state of the buffer, both the producer entity 108 and the consumer entity 110 can operate in a wait-free manner. For example, the producer entity 108 does not need to wait for the consumer entity 110 to catch up, and vice versa, as long as the buffer is not full or empty, respectively.

In some embodiments, the lapping/paperclipping module 214 may initiate the paperclipping operation particularly when the in-pointer of the producer entity 108 and the out-pointer of the consumer entity 110 are at the point of transitioning across the end of the buffer. This is crucial for ensuring the integrity of the state of the buffer. The functions of the paperclipping operation may include, but are not limited to, state recording, buffer integrity, and transaction validation.

In some embodiments, the paperclipping module 214 may record the state of the buffer just before the pointers wrap around the buffer, effectively paperclipping the state to reference when there is potential ambiguity. When either the producer entity 108 or the consumer entity 110 reaches the penultimate position in the buffer (i.e., one slot before wrapping around to the start), the paperclipping module 214 records the current lap of that entity. If the in-pointer and the out-pointer meet at the wrap-around point (e.g., the last slot of the buffer), the paperclipping module 214 uses the recorded lap, i.e., producer lap indicator and/or consumer lap indicator, to determine the correct state of the buffer, i.e. whether the buffer is actually full or empty. In a scenario where both the producer entity 108 and the consumer entity 110 simultaneously reach the wrap-around point, the paperclipping module 214 uses the recorded states to ensure that each entity, i.e., the producer entity 108 and the consumer entity 110 correctly interprets the state of the buffer and acts accordingly. By keeping track of the last known state, the paperclipping module 214 ensures the integrity of the buffer even when the in-pointer and the out-pointer are at the same location. In some embodiments, before any read or write operation is performed by the consumer entity 110 or the producer entity 108, respectively, the paperclipping module 214 may check the recorded state to validate whether the operation can proceed, ensuring that the producer entity 108 does not write to a full buffer and the consumer entity 110 does not read from an empty buffer.

In some embodiments, the reset module 216 may initiate a reset operation, allowing the producer entity 108 to overwrite old data with new data when the buffer is full and the consumer entity 110 is slow. When the buffer is full, the producer entity 108 may activate a flag signaling that no more data can be produced until the consumer entity 110 has caught up. The reset module 216 may initiate a four-way handshake between the producer entity 108 and the consumer entity 110. The producer entity 108 sets the flag (e.g., to 1) indicating the buffer is full. The consumer entity 110 acknowledges and resets its read position, and then the producer entity 108 resets its write operation. This is crucial for maintaining a continuous flow of data, especially in real-time systems.

It should be noted that components, described herein, can be configured in a variety of ways, including electronic circuitries, digital arithmetic and logic blocks, and memory systems in combination with software, firmware, and embedded technologies, etc., if bounded buffers are used in a consumper-producer paradigm.

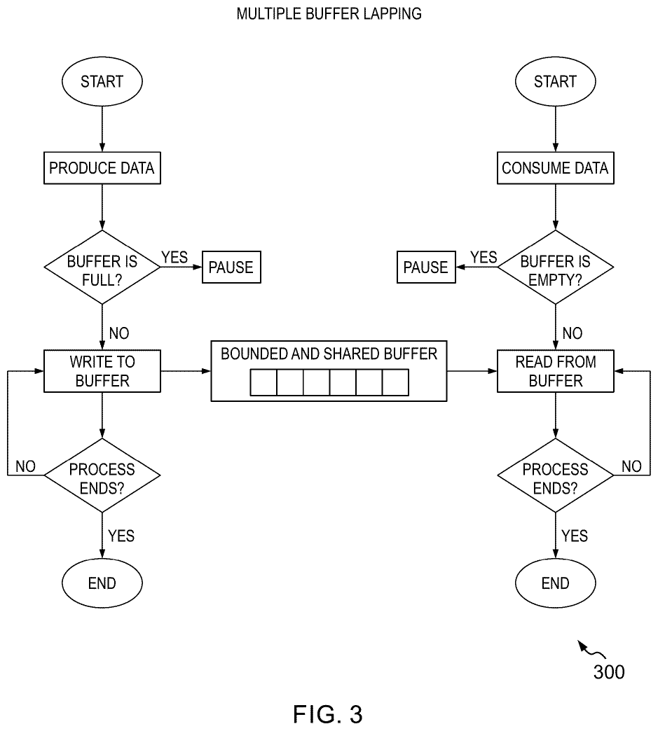

FIG. 3 illustrates a flow chart of an example method 300 for multiple buffer lapping, in accordance with embodiments of the present disclosure. It may be appreciated that the flow chart depicts both the producer entity side and the consumer entity side for the management of a bounded shared buffer.

At the start, the buffer is empty, both the consumer entity (e.g., 110 of FIG. 1) and the producer entity (e.g., 108 of FIG. 1) are at the first buffer slot (0), and the producer entity 108 must start first so that there is something to consume by the consumer entity 110. The producer entity 108 produces data in the first buffer slot and moves to the second buffer slot to indicate that an item is in the buffer. The consumer entity 110 can consume data from slot 0 and the producer entity 108 can produce data at slot 1. This is always the case when in-pointer does not equal out-pointer anywhere around the buffer. For parallel or simultaneous processing, there exists both an empty slot and a full slot at all times. As an example, the flow chart shows a buffer of size six. The current pointer position will be as shown below:

$$\begin{matrix}i \\ [ x ] [ ] … \\ o\end{matrix}$$

Logically, the buffer is circular, i.e., slot 0 connects to slot 5. Data can be both produced and consumed if in-pointer (i) does not equal out-pointer (o). When the in-pointer is equal to the out-pointer at any slot around the buffer, the buffer is either full or empty. The pointer position will be as shown below:

$$\begin{matrix}i i \\ Full [ x ] [ x ] [ x ] [ x ] [ x ] [ x ] or Empty [ ] [ ] [ ] [ ] [ ] [ ] \\ o o\end{matrix}$$

The producer and consumer lap indicators are updated when either of their pointers (in or out) are crossing over from slot 5 back to slot 0. Lap indicators are numbered either 0 or 1. When the consumer and producer lap indicators are equal, the buffer is empty, and when they are not equal, the buffer is full. If the buffer is full, the producer entity 108 pauses, and if the buffer is empty, the consumer entity 110 pauses. This process of knowing when the buffer is full or empty works fine until both pointers are equal at slot 5. This is the location where the lap indicators change from their value at slot 5 to what they will be at slot 0; all while the pointers are equal at the same location. The pointer position is as shown below:

$$\begin{matrix}01 \\ [ ] [ ] \\ i = o 5 [ ] [ ] 2 \\ [ ] [ ] \\ 43\end{matrix}$$

Both lap indicators are initially 0, and the in-pointer and out-pointer are at slot 5 (i.e., the buffer is empty). If the producer entity 108 decides to add an item, then its lap indicator, i.e., producer lap indicator changes to 1, and now the buffer appears to be full to the consumer entity 110 (since lap indicators are not equal). The pointer position is as shown below:

$$\begin{matrix}50 \\ i \\ [ x ] [ ] \\ o\end{matrix}$$

In a transaction, the producer entity 108 adds an item, updates the producer lap indicator (only at slot 5), and then moves the in-pointer to the next slot (transaction complete). The consumer entity 110 periodically checks if the buffer is full or empty and sees the producer lap indicator change while the in-pointer equals the out-pointer, consumes the item in the buffer, and moves to slot 0 while the producer entity 108 is still completing the transaction. The pointer position is as shown below:

$$\begin{matrix}45 \; 0 \\ i \\ [ ] [ ] [ ] \\ o\end{matrix}$$

In the results above, the in-pointer does not equal the out-pointer, and the consumer entity 110 can try to consume data from an empty buffer slot 0. This can also happen the other way around where the producer entity 108 tries to produce data into a full buffer slot 0. The pointer position is as shown below:

$$\begin{matrix}45 \; 0 \\ i \\ [ x ] [ x ] [ x ] \\ o\end{matrix}$$

To mitigate this synchronization issue, the paperclipping module (e.g., the lapping module 214 of FIG. 2) may initiate the paperclipping operation. Paperclipping is where the laps (i.e., paperclip indicators) are recorded at the slot before the lap change occurs (e.g., slot 4 above). The paperclip lap indicators may be recorded at any slot prior to the slot where the lap change occurs. The paperclipp lap indicators, i.e. producer paperclip indicator and the consumer paperclip indicator, are used for comparison when the in-pointer equals the out-pointer at, for example, slot five. The producer entity 108 (i.e., in-pointer) and the consumer entity 110 (i.e., out-pointer) can complete their transactions safely with an appropriate pause when the buffer is full or empty at slot five (slot before a lap is completed around the buffer).

Referring to FIG. 3, at the producer entity side, the production process begins. The producer entity (e.g., 108 of FIG. 1) creates or generates data that needs to be passed to the consumer entity (e.g., 110 of FIG. 1). The data may include, for example, sensor readings, computational results, user-generated content, or the like. Further, the system (or the server 102) checks if the buffer is full. This check is made using the lapping module (e.g., 214 of FIG. 2) where the producer entity's lap, i.e. position of the in-pointer (determined via the in-pointer module 210) is compared against the consumer entity's lap, i.e. position of the out-pointer (determined via the out-pointer 212) to determine the buffer's occupancy.

In some embodiments, if the buffer is full, the producer entity 108 must pause until an item is removed for a predetermined duration of time, for example, until the buffer is no longer full or the consumer entity 110 removes an item from the buffer. During this state, the producer entity 108 does not write new data to the buffer. This prevents the buffer from being overwritten with new data before the consumer entity 110 has processed the existing data. In some other embodiments, if the buffer is not full, the producer entity 108 may continue to the next step, i.e., the producer entity 108 writes the generated data to the buffer. The producer entity 108 writes the data to the buffer in its current in-pointer position, and the in-pointer is updated.

The server 102 checks if the data production is complete or if more data is expected. If the data production is complete, the production process ends. If the data production is not complete, it loops back to complete the data production.

At the consumer entity side, the consumption process begins. The consumer entity processes the data from the buffer. Further, the server 102 checks if the buffer is empty. This check is made using the lapping module (e.g., 214 of FIG. 2) where the producer entity's lap, i.e. position of the in-pointer (determined via the in-pointer module 210) is compared against the consumer entity's lap, i.e. position of the out-pointer (determined via the out-pointer 212) to determine the buffer's occupancy when in-pointer equals out-pointer.

In some embodiments, if the buffer is empty, the consumer entity 110 must pause for a predetermined duration of time, for example, until the buffer is no longer empty or the producer entity 108 adds an item to the buffer. During this state, the consumer entity 110 does not read data from the buffer. This prevents the consumer entity 110 from reading unpopulated slots of the buffer. In some other embodiments, if the buffer is not empty, the consumer entity 110 may continue to the next step, i.e., the consumer entity 110 reads the data from the buffer. The consumer entity 110 reads the data from the buffer at its current out-pointer position, and the out-pointer is updated.

The server 102 checks if the data consumption is complete or if more data is expected to be consumed. If the data consumption is complete, the consumption process ends. If the data consumption is not complete, it loops back to complete the consumption process.

The producer-consumer problem of determining an empty versus a full buffer has yielded many complicated, inefficient, and resource intensive solutions. The circular buffer is full or empty when the producer entity 108 out-laps the consumer entity 110 or the consumer entity 110 catches up to the producer entity 108, respectively. The original lap is recorded at (buffer size-2) for comparison (e.g., paperclip lap indicators); due to the lap change at (buffer size-1). In some embodiments, if the pointers move before the lap change, then the paperclip indicator may be read at slot 0 instead of buffer size-1, because that would then be where the lap change takes place.

Therefore, using multiple buffer lapping and paperclipping, the bounded and shared buffer allows the producer entity 108 to write data and the consumer entity 110 to read data in a synchronized manner, ensuring data integrity and process efficiency. The lapping operation allows the producer-consumer operations to happen concurrently and without requiring locks, thus enhancing performance, especially in systems that require real-time processing or have high data throughput demands. The method 300 presents a simplified view of these operations, abstracting the underlying complexity of the lapping logic, which carefully manages the pointers' positions to maintain the buffer's state.

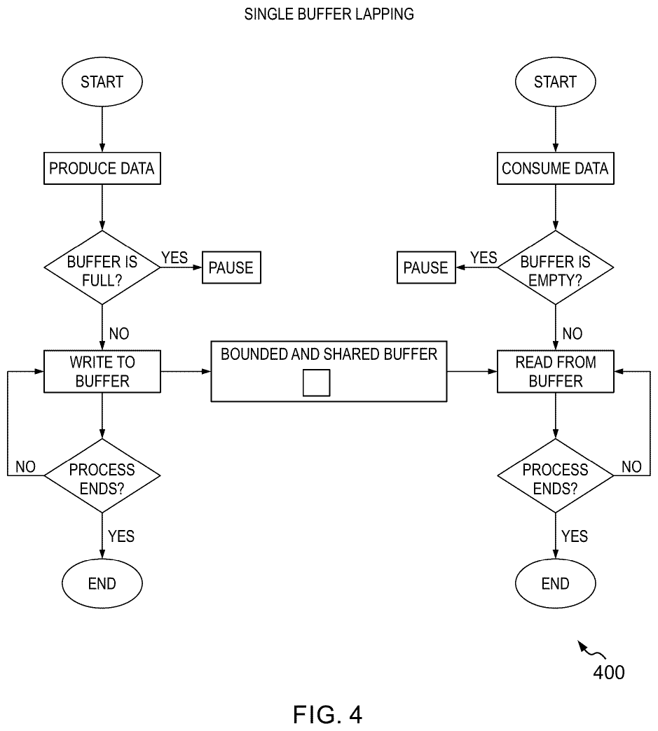

FIG. 4 illustrates a flow chart of an example method 400 for single buffer lapping, in accordance with embodiments of the present disclosure. It may be appreciated that the flow chart depicts both the producer entity side and the consumer entity side for management of one shared buffer slot.

A single buffer does not have pointers, i.e. in-pointer or out-pointer, because there is only one slot. This is shown below.
[ ] single buffer slot (slot 0)

Initially, both the consumer and producer lap indicators are set to 0. The laps can only be either 0 or 1. When the lap indicators are equal, the buffer is empty and when they are not equal, the buffer is full. When the producer entity 108 adds an item, its lap indicator is updated as shown below.
[x] Producer lap equals 1. Consumer lap still 0. Buffer full pause

When the consumer entity 110 removes an item, its lap indicator is updated as shown below.
[ ] Consumer lap equals 1. Producer lap still equals 1. Buffer empty pause.
[x] Producer lap equals 0. Consumer lap still 1. Buffer full pause
[ ] Consumer lap equals 0. Producer lap still equals 0. Buffer empty pause.

Referring to FIG. 4, at the producer entity side, the production process begins. The producer entity 108 creates or generates data that needs to be passed to the consumer entity 110. Further, the server 102 checks if the buffer is full.

In some embodiments, if the buffer is full, the producer entity 108 must pause for a predetermined duration of time, for example, until the buffer is no longer full or the consumer entity 110 removes an item. During this state, the producer entity 108 does not write new data to the buffer. This prevents the buffer from being overwritten with new data before the consumer entity 110 has processed the existing data. In some other embodiments, if the buffer is not full, the producer entity 108 may continue to the next step, i.e., the producer entity 108 writes the generated data to the buffer.

The server 102 checks if the data production is complete or if more data is expected. If the data production is complete, the production process ends. If the data production is not complete, it loops back to complete the data production.

At the consumer entity side, the consumption process begins. The consumer entity processes the data from the buffer. Further, the server 102 checks if the buffer is empty.

In some embodiments, if the buffer is empty, the consumer entity 110 must pause for a predetermined duration of time, for example, until the buffer is no longer empty or an item is added to the buffer. During this state, the consumer entity 110 does not read data from the buffer. In some other embodiments, if the buffer is not empty, the consumer entity 110 may continue to the next step, i.e., the consumer entity 110 reads the data from the buffer.

The server 102 checks if the data consumption is complete or if more data is expected to be consumed. If the data consumption is complete, the consumption process ends. If the data consumption is not complete, it loops back to complete the consumption process.

Therefore, the single buffer lapping ensures that both entities 108, 110 can work on the same buffer slot without the need for complex locking mechanisms. It facilitates synchronization by using a simple full/empty state indicator that determines whether the producer entity 108 can write to the buffer or if the consumer entity 110 can read from it. This mechanism is especially useful in systems where space is a premium, and the overhead of managing multiple buffer slots is undesirable. The single buffer lapping process is emblematic of systems that require tight control and predictable behavior from both producers and consumers of data.

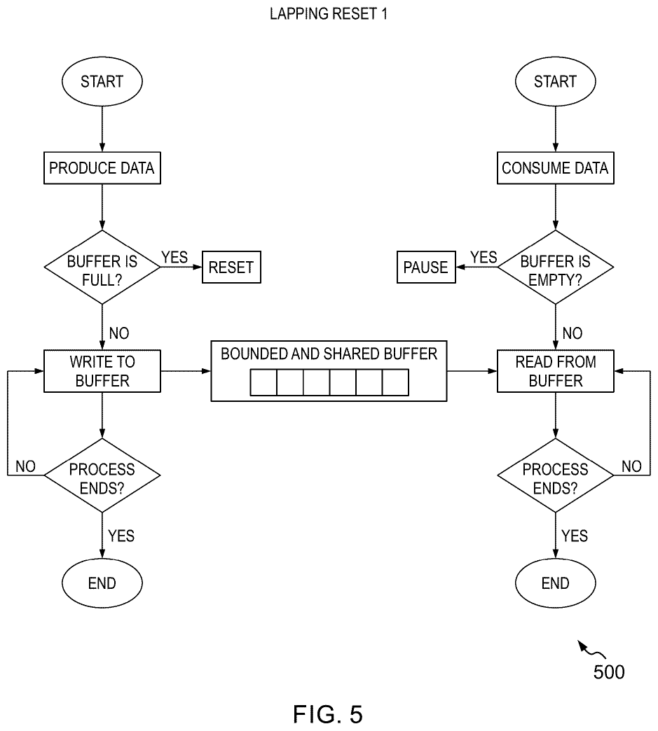

FIG. 5 illustrates a flow chart of an example method 500 for implementing lapping reset, in accordance with embodiments of the present disclosure.

The operation of lapping reset (implemented via the reset module 216 of FIG. 2) overwrites a full buffer instead of pausing when the consumer entity 110 is slow. In some scenarios, a system designer may want to overwrite old input data with more current data or they may not want to lose current data due to the buffer being already full with older data because of a slow consumer entity 110. In such scenarios, lapping reset may be initiated.

In some embodiments, when the producer entity 108 determines that the buffer is full and it cannot write, the producer entity 108 changes its flag (e.g., overPro) from 0 to 1 and pauses for consumer entity flag. The consumer entity 110 checks to see if an item is in the buffer, but identifies the producer entity flag set to 1. The consumer entity 110 pauses, resets its own lap indicator and out-pointer to 0, and then updates its flag (e.g., overCon) to 1 for the producer entity 108 to check. The producer entity 108 identifies the consumer entity flag set to 1, resets its lap indicator and in-pointer to 0, and its flag to 0, and remains paused for the consumer entity flag to be updated to 0. When the consumer entity 110 identifies the producer entity flag set to 0, it sets its flag to 0 and waits for an item to be produced. The producer entity 108 identifies the consumer entity flag set of 0 and produces data.

Therefore, the lapping reset is implemented as a four-way handshake that checks to see if both flags are 1 and finally if both flags are 0. This handshake prevents a race condition; because an item must first be produced to begin after reset/buffer empty.

Below is an example of a full and an empty buffer of size 10, where the pointers are equal at slot 9. In particular, the below example shows that the consumer entity 110 is about to consume, by updating its lap indicator to 1, but Chk paperclipping the real laps at slot 8 for a full buffer state at slot 9. The producer entity 108 would identify that the buffer is empty when looking at the lap indicators, but checks the Chk paperclip when at slot 9, which shows that the buffer is full and the consumer entity 110 is completing consumption in slot 9.

$$\begin{matrix}890 & Lap & Chk \\ 1 & 1 & \\ [ x ] [ ] [ x ] & & \\ o & 1 & 0\end{matrix}$$

The below example shows that the producer entity 108 is about to produce by updating its lap indicator to 0, but Chk paperclipping the real laps at slot 8 for an empty buffer state at slot 9. The consumer entity 110 may identify that the buffer is full when looking at the lap indicators, but knows to check Chk paperclip when at slot 9, which shows that the buffer is empty and the producer entity 108 is completing production in slot 9.

$$\begin{matrix}i & 0 & 1 \\ [ ] [ x ] [ ] & & \\ o & 1 & 1\end{matrix}$$

Therefore, paperclipping enables to show the true lap at the last buffer slot for the consumer entity 110 and the producer entity 108 with buffer size greater than one. The single slot buffer only updates lap indicators when transactions are complete because pointers are always equal.

The below example shows the producer entity 108 updating a buffer of size two at slot zero before moving to slot one. (A) Both producer entity 108 and consumer entity 110 have completed a lap around the buffer and updated their lap indicators to 1. (B) Producer entity 108 first updates the producer paperclip indicator with the current lap, produces an item, and moves from slot 0 (buffer size-2) to slot 1 (buffer size-1). (C) The consumer entity 110 first updates the consumer paperclip indicator with the current lap, consumes an item, and moves from slot 0 (buffer size-2) to slot 1 (buffer size-1). The buffer is empty now, only the producer entity 108 can produce and move back to slot 0, in the meantime the consumer entity 110 is constantly checking for an item to consume. (D) The producer entity 108 must change laps before moving back to slot 0. If a context switch/interrupt occurs at this point in time for the producer entity 108, the consumer entity 110 decides to check if the buffer is full or empty while the producer entity 108 is away; but checks the paperclip indicators instead of the lap indicators, because the consumer and producer pointers are equal at (buffer size-1) where all lap changes take place. The paperclip indicator indicates the consumer entity 110 that the buffer is empty; because the producer entity's 108 transaction is only complete when it moves to the next buffer slot, which in this case would be back to slot 0. (E) Producer entity 108 returns from context switch and completes transaction by moving back around to slot 0. Now consumer entity 110 can consume, the producer entity 108 can produce again, and they can do it at the same time autonomously.

$$\begin{matrix}\begin{matrix}10 & Lap & Chk \\ i & 1 & 0 \\ [ x ] [ ] [ x ] & & < - A \\ o & 1 & 0\end{matrix} \\ \begin{matrix}i & 0 & 1 \\ [ ] [ x ] & & < - B \\ o & 1 & 0\end{matrix} \\ \begin{matrix}i & 1 & 1 \\ [ ] [ ] & & < - C \\ o & 1 & 1\end{matrix} \\ \begin{matrix}i & 1 & 1 \\ [ x ] [ ] & & < - D \\ o & 1 & 1\end{matrix} \\ \begin{matrix}I & 0 & 1 & \\ [ x ] [ ] & & & < - E \\ o & & 1 & 1\end{matrix}\end{matrix}$$

Therefore, in accordance with embodiments of the present disclosure, the system 102 discussed herein is twice as fast as locking systems, because it consumes and produces at the same time with buffers greater than size one. There are no critical sections, because the consumer and producer entities update their own variables (no sharing). It is a thread/process safe processing chip that is hardware-independent, program language-agnostic, operating system independent, inexpensive, priority inversion/critical section free, starvation free, buffer space efficient, deadlock-free, simple to use, obstruction-free, lock-free, wait-free, works on both small and large data. Further, it may be appreciated that the system 102 may be implemented for, but not limited to, embedded systems, operating systems, and the like.

As an example, below is a pseudo code for single slot lapping. All variables initialized to zero.

```
while(1)
{
      /*produce another item in nextProduced*/
  if(lapPro != lapCon) //buffer full
  {
      continue;//continue re-iterates start of loop
  }
  buffer[0] = nextProduced; //produce next item in buffer
  lapPro = (lapPro + 1) % 2 // update the lap producer has completed 0 or
  1
}
while(1)
{
  if(lapPro == lapCon)// buffer is empty
  {
      continue;
  }
  nextConsumed = buffer[0]; //consume next item in buffer
  lapCon = (lapCon + 1) % 2 // update the lap the consumer has
completed 0 or 1
    /*consume the item in nextConsumed*/
}
```

As an example, below is the pseudo code for multiple slot lapping.

```
while(1)
{
  /*produce another item in nextProduced*/
  if(in + 2 == BUF_SIZE)
  {
      chkPro = lapPro; // mark lap two slots from start/finish for
      BUF_SIZE > 1
  }
  if(in==out)
  {
      if((in + 1) == BUF_SIZE &&chkPro != chkCon) //buffer full
      {
        continue;
      }
      else if(lapPro != lapCon) //buffer full
      {
        continue;
      }
  }
  buffer[in] = nextProduced; //produce next item in buffer
  if(in + 1 == BUF_SIZE) // Producer completed a lap around the buffer
  {
      lapPro = (lapPro + 1) % 2 // update the lap producer has
completed 0 or 1
  }
  in = (in + 1) % BUF_SIZE; //move the in pointer to the next buffer
  position
}
while(1)
{
  if(out + 2 == BUF_SIZE) //Consumer records lap at n − 2
  {
      chkCon = lapCon;
  }
  if(in==out)
  {
      if((out + 1) == BUF_SIZE &&chkPro == chkCon) //buffer empty
      {
        continue;
      }
      else if(lapPro == lapCon) //buffer empty
      {
        continue;
      }
  }
  nextConsumed = buffer[out]; //consume next item in buffer
  if((out + 1) == BUF_SIZE) // The consumer completed a lap around
the buffer
  {
      lapCon = (lapCon + 1) % 2 // update the lap the consumer has
completed 0 or 1
  }
  out = (out + 1) % BUF_SIZE; //move the out pointer to the next buffer
position
    /*consume the item in nextConsumed*/
  }
```

As an example, below is the pseudo code for multiple slot reset.

```
while(1)
{
  /*produce another item in nextProduced*/
  if(overPro == 1 &&overCon == 1) //safe overwrite condition, producer
and consumer reset
  {
      in = 0; //reset in-ptr
      lapPro = 0; //reset producer lap
      overPro = 0; // producer reset complete
  }
  else if(overPro == 1 || overCon == 1)//Waiting on consumer reset flag
  {
      continue;
  }
  if(in + 2 == BUF_SIZE)
  {
      chkPro = lapPro; // mark lap two slots from start/finish for
      BUF_SIZE > 1
  }
  if(in == out)
  {
      if((in + 1) == BUF_SIZE &&chkPro != chkCon) //buffer full
      {
        overPro = 1; //producer flags for overwrite
        continue; //reiterate loop
      }
      else if(lapPro != lapCon) //buffer full
      {
        overPro = 1; //producer flags for overwrite
        continue; //reiterate loop
      }
  }
  buffer[in] = nextProduced; //produce next item in buffer
  if(in + 1 == BUF_SIZE) // Producer completed a lap around the buffer
  {
      lapPro = (lapPro + 1) % 2 // update the lap producer has
completed 0 or 1
  }
  in = (in + 1) % BUF_SIZE; //move the in pointer to the next buffer
  position
  }
while(1)
{
  if(overPro == 1 &&overCon == 1)//waiting on producer reset
  {
      continue;
  }
  if(overPro==1) //check if producer is resetting
  {
      out = 0; //reset out-pointer
      lapCon = 0; //reset consumer lap
      overCon = 1; // consumer reset flag set
      continue; //re-iterate loop while producer resets
  }
  else if(overCon == 1)//only update in this case
  {
      overCon = 0; //reset complete
  }
  if(out + 2 == BUF_SIZE) //record consumer lap
  {
      chkCon = lapCon;
  }
  if(in==out)//producer initiates reset if buffer full
  {
      continue;
  }
  nextConsumed = buffer[out]; //consume next item in buffer
  if((out + 1) == BUF_SIZE) // The consumer completed a lap around
the buffer
  {
      lapCon = (lapCon + 1) % 2 // update the lap the consumer
hascompleted 0 or 1
  }
  out = (out + 1) % BUF_SIZE; //move the out pointer to the next buffer
position
    /*consume the item in nextConsumed*/
}
```

As an example, below is the pseudo code for single slot reset.

```
while(1)
{
    /*produce another item in nextProduced*/
  if(overPro == 1 &&overCon == 1) //safe overwrite condition, producer
and consumer reset
  {
    lapPro = 0; // reset producer lap
    overPro = 0; //reset producer flag
  }
  if(overpPro == 1 || overCon == 1)// fix wait on overCon to equal 0
  {
    continue;
  }
  if(lapPro != lapCon) //buffer full
  {
    overPro = 1; //producer flags for reset
    continue; //reiterate loop
  }
  buffer[0] = nextProduced; //produce next item in buffer
  lapPro = (lapPro + 1) % 2 // update the lap producer has completed 0 or
  1
}
while(1)
{
  if(overPro == 1 &&overCon == 1)
  {
    continue;
  }
  if(overPro == 1) //producer wants to overwrite old data
  {
    lapCon = 0; // reset consumer lap
    overCon = 1; //consumer flags for reset
    continue; //reiterate loop
  }
  else if(overCon == 1) //only change in this case
  {
    overCon = 0;// consumer resets flag
  }
  if(lapPro == lapCon)// buffer is empty
  {
    continue;
  }
  nextConsumed = buffer[0]; //consume next item in buffer
  lapCon = (lapCon + 1) % 2 // update the lap the consumer has
completed 0 or 1
  /*consume the item in nextConsumed*/
}
```

In some embodiments, multiple slot reset consumer catch up may be implemented as a four-way handshake where all consumer condition variables out, lapCon, and chkCon are set to equal the producer's respective condition variables once the consumer entity 110 sees the producer entity's 108 flag OverPro set to 1. The producer entity 108 does not write until the four-way handshake is complete or in other words the OverCon flag changes from 1 back to 0. This method has one less line of code than resetting all producer and consumer condition variables back to 0 except for the paperclip chkCon and chkPro which will be recorded at buffer size-2. The paperclip must be reset in the catch-up method because the reset values can be anywhere around the buffer including the location where lap changes occur. With the reset to 0, all variables are placed at the 0 location and the paperclip is recorded as normal before the lap change occurs. The four-way handshake is significant because both consumer entity 110 and producer entity 108 cease operations before reset and finally both consumer entity 110 and producer entity 108 restart operations after reset.

As an example, below is the pseudo code for multiple slot reset catch up.

```
while(1)
{
  /*produce another item in nextProduced*/
  if(overPro == 1 &&overCon == 1) //safe overwrite condition, producer
and consumer reset
{
    overPro = 0; // producer reset complete
}
  if(overCon == 1 || overPro == 1)//Waiting on consumer reset flag
{
    continue;
}
  if(in + 2 == BUF_SIZE)
{
    chkPro = lapPro; //update paperclip
  }
  if(in==out)
  {
    if((in + 1) == BUF_SIZE &&chkPro != chkCon) //buffer full
    {
      overPro = 1; //producer flags for overwrite
      continue; //reiterate loop
    }
    else if(lapPro != lapCon) //buffer full
    {
      overPro = 1; //producer flags for overwrite
      continue; //reiterate loop
    }
  }
  buffer[in] = nextProduced; //produce next item in buffer
  if(in + 1 == BUF_SIZE) // Producer completed a lap around the buffer
{
    lapPro = (lapPro + 1) % 2 // update the lap producer has completed
0 or 1
  }
  in = (in + 1) % BUF_SIZE; //move the in pointer to the next buffer
  position
}
while(1)//consumer loop
{
  if(overPro == 1 &&overCon == 1)//waiting on producer reset flag 0
  {
    continue;
  }
  if(overPro ==1) //check if producer is resetting
  {
    out = in; //reset out-pointer
    lapCon = lapPro; //reset consumer lap
    chkCon = chkPro; //reset consumer paperclip
    overCon = 1; // consumer reset flag set
    continue; //re-iterate loop while producer resets
  }
  else if(overCon == 1)//only update in this case
  {
    overCon = 0; //reset complete
  }
  if(out + 2 == BUF_SIZE) //record consumer lap
  {
    chkCon = lapCon;
  }
  if(in==out)//producer initiates reset if buffer full
  {
    continue;
  }
  nextConsumed = buffer[out]; //consume next item in buffer
  if((out + 1) == BUF_SIZE) // The consumer completed a lap around
the buffer
  {
    lapCon = (lapCon + 1) % 2 // update the lap the consumer has
completed 0 or 1
  }
  out = (out + 1) % BUF_SIZE; //move the out pointer to the next buffer
position
    /*consume the item in nextConsumed*/
}
```

As an example, below is the pseudo code for single slot reset catch up.

```
while(1)
{
    /*produce another item in nextProduced*/
  if(overPro == 1 &&overCon == 1) //indicate consumer handshake
  {
    overPro = 0; //reset producer flag
  }
  if(overpPro == 1 || overCon == 1)//wait on overCon to equal 0
  {
    continue;
  }
  if(lapPro != lapCon) //buffer full
  {
    overPro = 1; //producer flags for reset
    continue; //reiterate loop
  }
  buffer[0] = nextProduced; //produce next item in buffer
  lapPro = (lapPro + 1) % 2 // update the lap producer has completed 0 or
  1
}
while(1)
{
  if(overPro == 1 &&overCon == 1)
  {
    continue;
  }
  if(overPro == 1) //producer wants to overwrite old data
  {
    lapCon = lapPro; // reset consumer lap
    overCon = 1; //consumer flags for reset
    continue; //reiterate loop
  }
  else if(overCon == 1) //only change in this case
  {
    overCon = 0;// consumer resets flag
  }
  if(lapPro == lapCon)// buffer is empty
  {
    continue;
  }
  nextConsumed = buffer[0]; //consume next item in buffer
  lapCon = (lapCon + 1) % 2 // update the lap the consumer has
completed 0 or 1
    /*consume the item in nextConsumed*/
}
```

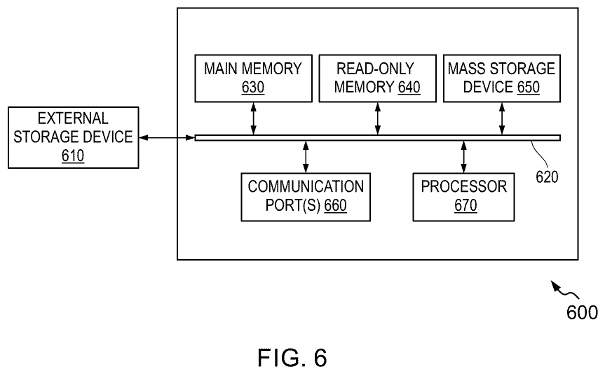

FIG. 6 illustrates an example computer system 600 in which or with which embodiments of the present disclosure may be utilized in accordance with embodiments of the present disclosure. In some embodiments, the server 102 or the system 102 may be implemented as the computer system 600.

As shown in FIG. 6, the computer system 600 may include an external storage device 610, a bus 620, a main memory 630, a read-only memory 640, a mass storage device 650, communication port(s) 660, and a processor 670. A person skilled in the art will appreciate that the computer system 600 may include more than one processor and communication ports. The processor 670 may include various modules associated with embodiments of the present disclosure. The communication port(s) 660 may be any of an RS-232 port for use with a modem-based dialup connection, a 10/100 Ethernet port, a Gigabit or 10 Gigabit port using copper or fiber, a serial port, a parallel port, or other existing or future ports. The communication port(s) 660 may be chosen depending on a network, such as a Local Area Network (LAN), Wide Area Network (WAN), or any network to which the computer system 600 connects.

The main memory 630 may be a random-access memory (RAM), or any other dynamic storage device commonly known in the art. The read-only memory 640 may be any static storage device(s) e.g., but not limited to, a Programmable Read Only Memory (PROM) chips for storing static information e.g., start-up or Basic Input/Output System (BIOS) instructions for the processor 670. The mass storage device 650 may be any current or future mass storage solution, which can be used to store information and/or instructions. Exemplary mass storage device 650 includes, but is not limited to, Parallel Advanced Technology Attachment (PATA) or Serial Advanced Technology Attachment (SATA) hard disk drives or solid-state drives (internal or external, e.g., having Universal Serial Bus (USB) and/or Firewire interfaces), one or more optical discs, Redundant Array of Independent Disks (RAID) storage, e.g. an array of disks.

The bus 620 communicatively couples the processor 670 with the other memory, storage, and communication blocks. The bus 620 may be, e.g. a Peripheral Component Interconnect (PCI)/PCI Extended (PCI-X) bus, Small Computer System Interface (SCSI), USB, or the like, for connecting expansion cards, drives, and other subsystems as well as other buses, such a front side bus (FSB), which connects the processor 670 to the computer system 600.

Optionally, operator and administrative interfaces, e.g. a display, keyboard, joystick, and a cursor control device, may also be coupled to the bus 620 to support direct operator interaction with the computer system 600. Other operator and administrative interfaces can be provided through network connections connected through the communication port(s) 660. The components described above are meant only to exemplify various possibilities. In no way should the aforementioned exemplary computer system 600 limit the scope of the present disclosure.

The methods described herein may be performed using the systems described herein. In addition, it is contemplated that the methods described herein may be performed using systems different than the systems described herein. Moreover, the systems described herein may perform the methods described herein and may perform or execute instructions stored in a non-transitory computer-readable storage medium (CRSM). The CRSM may comprise any electronic, magnetic, optical, or other physical storage device that stores executable instructions. The instructions may comprise instructions to cause a processor to perform or control performance of operations of the proposed methods. It is also contemplated that the systems described herein may perform functions or execute instructions other than those described in relation to the methods and CRSMs described herein.

Furthermore, the CRSMs described herein may store instructions corresponding to the methods described herein, and may store instructions which may be performed or executed by the systems described herein. Furthermore, it is contemplated that the CRSMs described herein may store instructions different than those corresponding to the methods described herein, and may store instructions which may be performed by systems other than the systems described herein.

The methods, systems, and CRSMs described herein may include the features or perform the functions described herein in association with any one or more of the other methods, systems, and CRSMs described herein.

In some embodiments the method or methods described above may be executed or carried out by a computing system (for example, the computer system 600 of FIG. 6) including a tangible computer-readable storage medium, also described herein as a storage machine, that holds machine-readable instructions executable by a logic machine (i.e. a processor or programmable control device) to provide, implement, perform, and/or enact the above described methods, processes and/or tasks. When such methods and processes are implemented, the state of the storage machine may be changed to hold different data. For example, the storage machine may include memory devices such as various hard disk drives, CD, or DVD devices. The logic machine may execute machine-readable instructions via one or more physical information and/or logic processing devices. For example, the logic machine may be configured to execute instructions to perform tasks for a computer program. The logic machine may include one or more processors to execute the machine-readable instructions. The computing system may include a display subsystem to display a graphical user interface (GUI) or any visual element of the methods or processes described above. For example, the display subsystem, storage machine, and logic machine may be integrated such that the above method may be executed while visual elements of the disclosed system and/or method are displayed on a display screen for user consumption. The computing system may include an input subsystem that receives user input. The input subsystem may be configured to connect to and receive input from devices such as a mouse, keyboard or gaming controller. For example, a user input may indicate a request that certain task is to be executed by the computing system, such as requesting the computing system to display any of the above described information, or requesting that the user input updates or modifies existing stored information for processing. A communication subsystem may allow the methods described above to be executed or provided over a computer network. For example, the communication subsystem may be configured to enable the computing system to communicate with a plurality of personal computing devices. The communication subsystem may include wired and/or wireless communication devices to facilitate networked communication. The described methods or processes may be executed, provided, or implemented for a user or one or more computing devices via a computer-program product such as via an application programming interface (API).

Since many modifications, variations, and changes in detail can be made to the described preferred embodiments of the disclosure, it is intended that all matters in the foregoing description and shown in the accompanying drawings be interpreted as illustrative and not in a limiting sense. Thus, the scope of the invention should be determined by the appended claims and their legal equivalents.

1. A system for data synchronization, comprising:
a processor; and
a memory operatively coupled to the processor, the memory comprising processor-executable instructions which, when executed, cause the processor to:
determine a producer lap indicator, associated with a producer entity, corresponding to a buffer, wherein the producer lap indicator tracks a lap of an in-pointer around the buffer, wherein the lap of the in-pointer is completed when the in-pointer returns to a corresponding starting point after traversing the buffer;
determine a consumer lap indicator associated with a consumer entity, wherein the consumer lap indicator tracks a lap of an out-pointer around the buffer, wherein the lap of the out-pointer is completed when the out-pointer returns to a corresponding starting point after traversing the buffer;
determine a state of the buffer based on the producer lap indicator and the consumer lap indicator; and
in response to a determination of the state of the buffer being full or empty, enable data synchronization based on initial lapping and/or paperclipping at the buffer.

2. The system of claim 1, wherein to initiate the paperclipping, the processor is configured to record a producer paperclip indicator and a consumer paperclip indicator prior to a change in the respective producer lap indicator and the consumer lap indicator associated with the producer entity and the consumer entity, and determine the state of the buffer based on the producer paperclip indicator and the consumer paperclip indicator.

3. The system of claim 2, wherein to initiate the lapping, the processor is configured to:
determine a position of the in-pointer, associated with the producer entity, corresponding to the buffer;
determine a position of the out-pointer associated with the consumer entity;
determine the state of the buffer further based on the position of the in-pointer and the position of the out-pointer;
in response to the state of the buffer being full, restrict the producer entity to write data to the buffer, or the consumer entity to read data from the buffer until an item is removed or added respectively, for a predetermined duration of time; and
in response to the state of the buffer being empty, enable the producer entity to write the data to the buffer at the position of the in-pointer in the buffer, or the consumer entity to read the data from the position of the out-pointer in the buffer.

4. The system of claim 3, wherein the processor is further configured to initiate the paperclipping based on the position of the in-pointer being same as the position of the out-pointer where lap change occurs.

5. The system of claim 3, wherein in response to the state of the buffer being full, the processor is configured to set a producer flag associated with the producer entity to 1, indicating that the buffer is full.

6. The system of claim 5, wherein the process or is further configured to:
reset the consumer lap indicator and the position of the out-pointer to 0; and
set a consumer flag associated with the consumer entity to 1.

7. The system of claim 6, wherein the process or is further configured to:
based on the consumer flag being set to 1, reset the producer lap indicator and the position of the in-pointer to 0, and the producer flag to 0;
based on the producer flag being set to 0, set the consumer flag to 0 and wait for the data to be written to the buffer; and
based on the consumer flag being set to 0, enable the producer entity to write the data to the buffer.

8. The system of claim 5, wherein the processor is further configured to:
set a consumer flag associated with the consumer entity, the position of the out-pointer, the consumer lap indicator, and the consumer paperclip indicator as equal to the respective producer flag, the position of the in-pointer, the producer lap indicator, and the consumer paperclip indicator; and
restrict the producer entity to write the data until the consumer flag is 0.

9. The system of claim 1, wherein the state of the buffer is empty when the producer lap indicator and the consumer lap indicator are equal and/or a position of the in-pointer is equal to a position of the out-pointer, and wherein the state of the buffer is full when the producer lap indicator and the consumer lap indicator are not equal.

10. A method for data synchronization, comprising:
determining, by a processor, a producer lap indicator, associated with a producer entity, corresponding to a buffer, wherein the producer lap indicator tracks a lap of an in-pointer around the buffer, wherein the lap of the in-pointer is completed when the in-pointer returns to a corresponding starting point after traversing the buffer;
determining, by the processor, a consumer lap indicator associated with a consumer entity, wherein the consumer lap indicator tracks a lap of an out-pointer around the buffer, wherein the lap of the out-pointer is completed when the out-pointer returns to a corresponding starting point after traversing the buffer;
determining, by the processor, a state of the buffer based on the producer lap indicator and the consumer lap indicator; and
in response to determining that the state of the buffer is full or empty, enabling, by the processor, data synchronization based on initiating lapping and/or paperclipping at the buffer.

11. The method of claim 10, wherein to initiate the paperclipping, the method comprises recording, by the processor, a producer paperclip indicator and a consumer paperclip indicator prior to a change in the respective producer lap indicator and the consumer lap indicator associated with the producer entity and the consumer entity; and determining, by the processor, the state of the buffer further based on the producer paperclip indicator and the consumer paperclip indicator.

12. The method of claim 11, wherein to initiate the lapping, the method further comprises:
determining, by the processor, a position of the in-pointer, associated with the producer entity, corresponding to the buffer;
determining, by the processor, a position of the out-pointer associated with the consumer entity;
determining, by the processor, the state of the buffer further based on the position of the in-pointer and the position of the out-pointer;
in response to the state of the buffer being full, restricting, by the processor, the producer entity to write data to the buffer, or the consumer entity to read data from the buffer until an item is removed or added respectively, for a predetermined duration of time; and
in response to the state of the buffer being empty, enabling, by the processor, the producer entity to write the data to the buffer at the position of the in-pointer in the buffer, or the consumer entity to read the data from the position of the out-pointer in the buffer.

13. The method of claim 12, wherein initiating the paperclipping is based on the position of the in-pointer being same as the position of the out-pointer where lap change occurs.

14. The method of claim 12, wherein in response to the state of the buffer being full, the method comprises setting, by the processor, a producer flag associated with the producer entity to 1, indicating that the buffer is full.

15. The method of claim 14, further comprising:
resetting, by the processor, the consumer lap indicator and the position of the out-pointer to 0; and
setting, by the processor, a consumer flag associated with the consumer entity to 1.

16. The method of claim 15, further comprising:
based on the consumer flag being set to 1, resetting, by the processor, the producer lap indicator and the position of the in-pointer to 0, and the producer flag to 0;
based on the producer flag being set to 0, setting, by the processor, the consumer flag to 0 and waiting for the data to be written to the buffer; and
based on the consumer flag being set to 0, enabling, by the processor, the producer entity to write the data to the buffer.

17. The method of claim 14, further comprising:
setting, by the processor, a consumer flag associated with the consumer entity, the position of the out-pointer, the consumer lap indicator, and the consumer paperclip indicator as equal to the respective producer flag, the position of the in-pointer, the producer lap indicator, and the producer paperclip indicator; and
restricting, by the processor, the producer entity to write the data until the consumer flag is 0.

18. The method of claim 10, wherein the state of the buffer is empty when the producer lap indicator and the consumer lap indicator are equal and/or a position of the in-pointer is equal to a position of the out-pointer, and wherein the state of the buffer is full when the producer lap indicator and the consumer lap indicator are not equal.

19. A non-transitory computer-readable medium comprising executable instructions that cause a processor to:
determine a producer lap indicator, associated with a producer entity, corresponding to a buffer, wherein the producer lap indicator tracks a lap of an in-pointer around the buffer, wherein the lap of the in-pointer is completed when the in-pointer returns to a corresponding starting point after traversing the buffer;
determine a consumer lap indicator associated with a consumer entity, wherein the consumer lap indicator tracks a lap of an out-pointer around the buffer, wherein the lap of the out-pointer is completed when the out-pointer returns to a corresponding starting point after traversing the buffer;
determine a state of the buffer based on the producer lap indicator and the consumer lap indicator; and
in response to a determination of the state of the buffer being full or empty, enable data synchronization based on initiating lapping and/or paperclipping at the buffer.
